(19) United States
(12) Patent Application Publication
(10) Pub. No.: US 2011/0155212 A1
(43) Pub. Date: Jun. 30, 2011

(54) SOLAR PANEL ASSEMBLY WITH HEAT DISSIPATION IMPROVEMENT

(75) Inventors: Chen-Yu Yang, Keelung City (TW); Cheng-Hsin Chen, Changhua County (TW); Hsien-Hsin Yeh, Taipei County (TW)

(73) Assignee: Du Pont Apollo Limited, Hong Kong (HK)

(21) Appl. No.: 12/964,729

(22) Filed: Dec. 9, 2010

Related U.S. Application Data
(60) Provisional application No. 61/290,277, filed on Dec. 28, 2009.

(51) Int. Cl. H01L 31/052

(52) U.S. Cl. 136/246

(57) ABSTRACT

A solar panel assembly includes a solar panel, a gasket, a metal frame and a thermal paste. The solar panel has an upper glass substrate and a lower substrate. The gasket seals and sandwiches respective edges of the upper and lower substrates. The metal frame encloses the gasket. The thermal paste is disposed along the gasket or to enclose the gasket.

### RELATED APPLICATIONS

This application claims priority to U.S. Provisional Application Ser. No. 61/290,277, filed Dec. 28, 2009, which is herein incorporated by reference.

### BACKGROUND

1. Field of Invention

The present invention relates to heat dissipation and more particularly to heat dissipation from a solar panel assembly.

2. Description of Related Art

Photovoltaic sun concentrators used with photovoltaic (PV) solar cells provide a way of making solar electric energy cost competitive compared to conventional electric generation technologies such as fossil fuels. The concentration of the sun's energy creates heat and thus it is necessary to cool the PV solar cells that are exposed to concentrate solar radiation. When PV cells are operated under normal solar radiation, they may reach temperatures of up to 70-90° C. and several hot spots over one hundred degrees. When concentrators are used, these devices may reach temperatures of several hundred degrees if cooling is not provided. Such high temperatures lead to several negative effects. For example, cell efficiency decreases proportionally to temperature and electrical power output is reduced. In addition, many materials used in PV cells have an operating range that typically does not exceed +150 degrees Celsius.

For the forgoing reasons, there is a need for a solar panel assembly to employ a better heat dissipation solution.

### SUMMARY

In accordance with an aspect of the present invention, a solar panel assembly includes a solar panel, a gasket, a metal frame and a thermal paste. The solar panel has an upper glass substrate and a lower substrate. The gasket seals and sandwiches respective edges of the upper and lower substrates. The metal frame encloses the gasket. The thermal paste is disposed along the gasket and interconnected between the upper glass substrate and the metal frame, or between the lower substrate and the metal frame.

According to one embodiment of the present invention, the thermal paste has a in greater thermal conductivity than the gasket has.

According to another embodiment of the present invention, the thermal paste comprises silicon compounds, oxide compounds, carbon compounds, silver compounds or any combinations thereof.

According to another embodiment of the present invention, the metal frame exposes two opposite edges of the gasket.

According to another embodiment of the present invention, the thermal paste fully seals the two opposite edges of the gasket, which are exposed by the metal frame.

According to another embodiment of the present invention, the metal frame comprises aluminum or steel.

According to another embodiment of the present invention, the solar panel assembly further includes a junction box secured under the lower substrate.

According to another embodiment of the present invention, the metal frame and thermal paste fully seal the gasket.

According to another embodiment of the present invention, the thermal paste, interconnected between the upper glass substrate and the metal frame, has a width ranging from about 0.5 mm to about 1 mm.

In accordance with another aspect of the present invention, a solar panel assembly includes a solar panel, a gasket and a metal frame. The solar panel includes an upper glass substrate and a lower substrate. The gasket seals and sandwiches respective edges of the upper and lower substrates, wherein the gasket includes silicon compounds, oxide compounds, carbon compounds, silver compounds or any combinations thereof. The metal frame encloses the gasket.

According to one embodiment of the present invention, the metal frame exposes two opposite edges of the gasket.

According to another embodiment of the present invention, the metal frame comprises aluminum or steel.

According to another embodiment of the present invention, the solar panel assembly further includes a junction box secured under the lower substrate.

According to another embodiment of the present invention, the solar panel assembly further includes a thermal paste disposed along the gasket, and interconnected between the upper glass substrate and the metal frame, or between the lower substrate and the metal frame.

According to another embodiment of the present invention, the solar panel assembly further includes a thermal paste fully enclosing the gasket, and interconnected between the upper glass substrate and the gasket, between the lower substrate and the gasket, and between the gasket and the metal frame.

It is to be understood that both the foregoing general description and the following detailed description are by examples, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings;

FIG. 1 illustrates a cross-sectional view of a solar panel assembly according to one embodiment of this invention;

FIG. 1A illustrates an enlarged view of a thermal paste within the solar panel assembly as illustrated in FIG. 1;

FIG. 2 illustrates a cross-sectional view of a solar panel assembly according to another embodiment of this invention; and

FIG. 3 illustrates a cross-sectional view of a solar panel assembly according to still another embodiment of this invention.

### DESCRIPTION OF THE PREFERRED EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

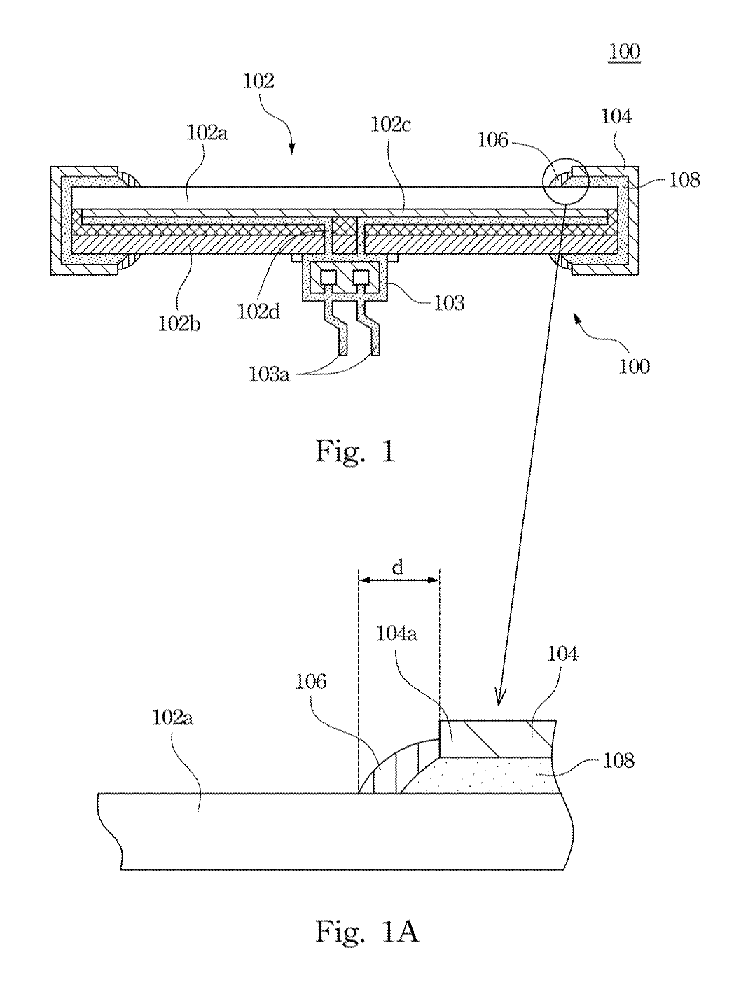

FIG. 1 illustrates a cross-sectional view of a solar panel assembly according to one embodiment of this invention. The solar panel assembly 100 includes a solar panel 102 with two opposite edges clamped by gaskets and frames. The solar panel 102 includes a photovoltaic film 102c, which is sandwiched between an upper glass substrate 102a and a lower substrate 102b, to convert solar radiation into direct current electricity. A junction box 103 is secured under the lower substrate 102b to contain all output terminals 102d extending from the photovoltaic film 102c therein. Two power cables 103a extend from the junction box 103 for connection to a load or a storage battery. During the solar radiation converting into electricity, the solar panel 102 may have hot spots occurred thereon. In order to prevent the hot spots on the upper glass substrate 102a or a lower substrate 102b, a thermal paste is used to enhance heat dissipation.

As illustrated in FIG. 1, two opposite edges of the solar panel 102 is sealed and sandwiched by the gasket 108, and further enclosed by a metal frame 104. The gasket 108 is made from elastic plastic materials, which serves as a buffer between the substrates, e.g. 102a or 102b, and the metal frame 104 such that the metal frame 128 would not damage the glass substrate. However, the conventional gasket 108 is not a good heat conductor compared to the metal frame 104 that the hot spot occurred on the substrates, e.g. 102a or 102b may not dissipate through the gasket 108. In this embodiment, a thermal paste 106 is applied along the gasket 108 and interconnected between the upper glass substrate 102a and the metal frame 104, or between the lower substrate 102b and the metal frame 104.

Referring to FIG. 1A, an enlarged view of the thermal paste 106 within the solar panel assembly is illustrated. The thermal paste 106 fully seals the two opposite edges of the gasket 108, which are exposed by the metal frame 104 (such as an aluminum or steel frame). That is, the metal frame 104 and the thermal paste 106 fully seal the gasket 108. In addition, the thermal paste 106 is interconnected between the upper glass substrate 102a and an edge 104a of the metal frame 104. When the thermal paste 106 is applied on the upper glass substrate 102a, the thermal paste 106 can be applied by a width d ranging from about 0.5 mm to about 1 mm such that the thermal paste 106 would not occupy too much area of the upper glass substrate 102a. When the thermal paste 106 is applied on the lower substrate 102a, there is no width restriction for the thermal paste 106. When hot spots occur on the upper glass substrate 102a, they would be transferred to metal frame 104 through the thermal paste 106. Moreover, the thermal paste 106 itself also increases the heat dissipation area. The metal frame can be designed to have outer heat sink fins (not illustrated in drawings) to assist with the heat dissipation. The thermal paste 106 can be made from the materials, which has a greater thermal conductivity than the gasket 108 has. For example, the thermal paste 106 can be silicon compound, oxide compound, carbon compound, silver compound or any combinations thereof.

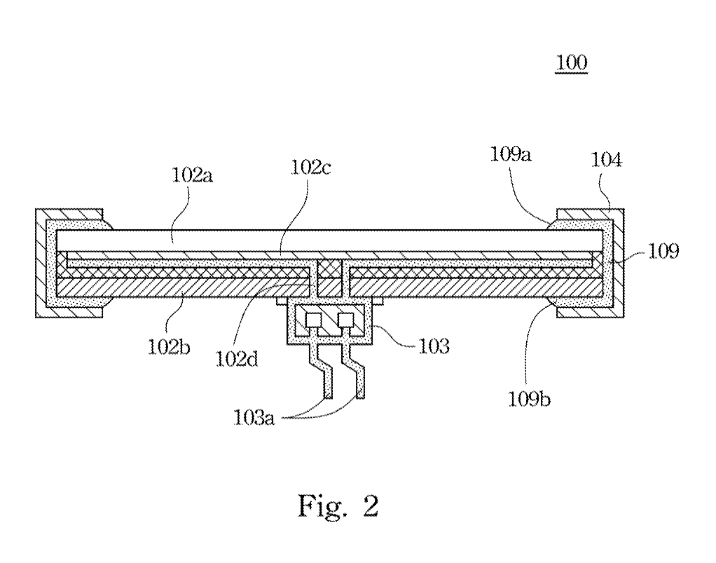

FIG. 2 illustrates a cross-sectional view of a solar panel assembly according to another embodiment of this invention. As illustrated in FIG. 2, two opposite edges of the solar panel 102 is sealed and sandwiched by the gasket 109, and further enclosed by a metal frame 104. Two opposite edges (109a, 109b) of the gasket 109 are exposed by the metal frame 104. The gasket 109 is made from elastic plastic materials, which serves as a buffer between the substrates, e.g. 102a or 102b, and the metal frame 104 such that the metal frame 128 would not damage the glass substrate. In this embodiment, the gasket 109 is made from elastic plastic materials, which have a better thermal conductivity than a conventional gasket. For example, the elastic plastic materials can be mixed with silicon compounds, oxide compounds, carbon compounds, silver compounds or any combinations thereof to produce the desired gasket 109. When hot spots occur on the upper glass substrate 102a or the lower substrate 102b, they would be transferred to metal frame 104 through the gasket 109. The metal frame can be designed to have outer heat sink fins (not illustrated in drawings) to contribute the heat dissipation.

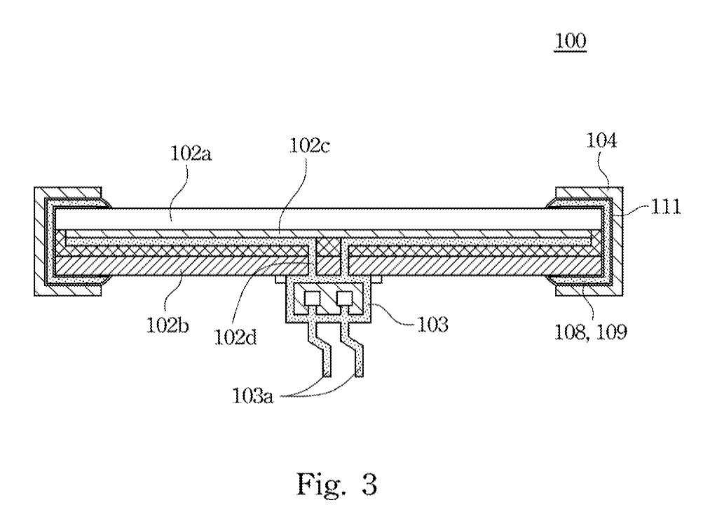

FIG. 3 illustrates a cross-sectional view of a solar panel assembly according to still another embodiment of this invention. A thermal paste 111, which has a greater thermal conductivity than the gasket (108 or 109) has, can be applied onto surfaces of the gasket (108 or 109). The thermal paste 111 fully encloses the gasket, such that the thermal paste 106 is interconnected between the metal frame 104 and the gasket (108 or 109), and also between either one of the two substrates (102a or 102b) and the gasket (108 or 109).

According to the above-discussed embodiments, the solar panel assembly herein provides an effective solution for the solar panel to transfer heat to its outer metal or heat sink. By adding a thermal paste to interconnect the glass substrate and the metal or using a gasket with a better thermal conductivity, hot spots occurred on the glass substrates can be avoid.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A solar panel assembly comprising:
a solar panel comprising an upper glass substrate and a lower substrate;
a gasket sealing and sandwiching respective edges of the upper and lower substrates;
a metal frame enclosing the gasket; and
a thermal paste disposed along the gasket and interconnected between the upper glass substrate and the metal frame, or between the lower substrate and the metal frame.

2. The solar panel assembly of claim 1, wherein the thermal paste has a greater thermal conductivity than the gasket has.

3. The solar panel assembly of claim 1, wherein the thermal paste comprises silicon compounds, oxide compounds, carbon compounds, silver compounds or any combinations thereof.

4. The solar panel assembly of claim 1, wherein the metal frame exposes two opposite edges of the gasket.

5. The solar panel assembly of claim 4, wherein the thermal paste fully seals the two opposite edges of the gasket, which are exposed by the metal frame.

6. The solar panel assembly of claim 1, wherein the metal frame comprises aluminum or steel.

7. The solar panel assembly of claim 1, further comprising a junction box secured under the lower substrate.

8. The solar panel assembly of claim 1, wherein the metal frame and thermal paste fully seal the gasket.

9. The solar panel assembly of claim 1, wherein the thermal paste, interconnected between the upper glass substrate and the metal frame, comprises a width ranging from about 0.5 mm to about 1 mm.

10. A solar panel assembly comprising:
a solar panel comprising an upper glass substrate and a lower substrate;
a gasket sealing and sandwiching respective edges of the upper and lower substrates, wherein the gasket comprises silicon compounds, oxide compounds, carbon compounds, silver compounds or any combinations thereof; and
a metal frame enclosing the gasket.

11. The solar panel assembly of claim 10, wherein the metal frame exposes two opposite edges of the gasket.

12. The solar panel assembly of claim 10, wherein the metal frame comprises aluminum or steel.

13. The solar panel assembly of claim 10, further comprising a junction box secured under the lower substrate.

14. The solar panel assembly of claim 10, further comprising a thermal paste disposed along the gasket and interconnected between the upper glass substrate and the metal frame, or between the lower substrate and the metal frame.

15. The solar panel assembly of claim 10, further comprising a thermal paste fully enclosing the gasket, the thermal paste is interconnected between the upper glass substrate and the gasket, between the lower substrate and the gasket, and between the gasket and the metal frame.
